(19) United States
(12) Patent Application Publication
(10) Pub. No.: US 2024/0194481 A1
(43) Pub. Date: Jun. 13, 2024

(54) METHOD OF FORMING THIN FILM USING MATERIAL OF CHEMICAL PURGE

(71) Applicant: EGTM Co., Ltd., Suwon-si (KR)

(72) Inventors: Kyu Ho CHO, Suwon-si (KR); Jae Min KIM, Suwon-si (KR); Ha Na KIM, Suwon-si (KR); Ji Yeon HAN, Suwon-si (KR); Duck Hyeon SEO, Suwon-si (KR); Ju Hwan JEONG, Suwon-si (KR); Hyun Ju JUNG, Suwon-si (KR)

(73) Assignee: EGTM Co., Ltd., Suwon-si (KR)

(21) Appl. No.: 18/518,718

(22) Filed: Nov. 24, 2023

(30) Foreign Application Priority Data
Nov. 24, 2022 (KR) 10-2022-0159782

(51) Int. Cl. H01L 21/02

(52) U.S. Cl. CPC H01L 21/02337; H01L 21/02186; H01L 21/02208; H01L 21/0228

(57) ABSTRACT

Disclosed is a method of forming a thin film using a chemical purge material, the method comprising supplying a metal precursor to the inside of a chamber oh which a substrate is placed; purging the interior of the chamber; supplying a reactant to the inside of the chamber so that the reactant reacts with the metal precursor to form the thin film; and supplying a chemical purge material to the inside of the chamber so that a portion of the reactant is removed.

### TECHNICAL FIELD

The present invention relates to a method of forming a thin film. More particularly, the present invention relates to a method of forming a thin film that is capable of removing over-adsorbed reactive substances using a chemical purge material.

### BACKGROUND

Currently, in relation to a capacitor of DRAM devices, a research on MIM (Metal/Insulator/Metal) capacitor using metal electrodes is continuously underway, and a titanium nitride (TiN) is widely used as an electrode material.

In the field of semiconductor processing, the deposition process is an important process of depositing materials on a substrate, and as the external appearance of electronic devices continues to shrink and the density of equipment increases, the aspect ratio of features increasingly increases. Therefore, processes with a good step coverage are attracting attention, and in particular, atomic layer deposition (ALD) is of particular interest.

Since the titanium nitride film operates as the upper and lower electrodes in the capacitor, excellent step coverage must be achieved. However, in general, ammonia (NH3), a widely used reactant in the titanium nitride film deposition process, is superadsorbed by intermolecular interactions such as hydrogen bonding or van der Waals attraction to form multilayers, and is not completely removed by physical purging.

Overadsorption of NH3 leads to overadsorption of subsequent precursor, making it difficult to form a conformal thin film, and causes step coverage deterioration, so a technology that can solve this problem is required.

An object of the present invention is to provide a method of forming a thin film with good step coverage.

Another object of the present invention is to provide a method of forming a thin film that can significantly improve the step coverage of the thin film by effectively removing overadsorbed reactive substances.

Other objects of the present invention will become more apparent from the following detailed description.

### SUMMARY

Disclosed is a method of forming a thin film using a chemical purge material, the method comprising supplying a metal precursor to the inside of a chamber oh which a substrate is placed; purging the interior of the chamber; supplying a reactant to the inside of the chamber so that the reactant reacts with the metal precursor to form the thin film; and supplying a chemical purge material to the inside of the chamber so that a portion of the reactant is removed.

The chemical purge material may be represented by the following Chemical Formula 1:

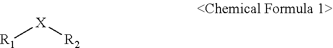

wherein X is a chalcogen element including O, S, Se, Te, and Po, and
R1 or R2 are each independently selected from hydrogen, an alkyl group with 1 to 8 carbon atoms, a cycloalkyl group with 3 to 6 carbon atoms, an aryl group with 6 to 12 carbon atoms, a halogen element, or an alkyl halide.

The chemical purge material may be represented by the following Chemical Formula 2:

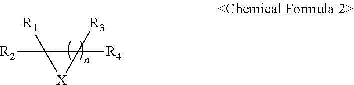

wherein X is a chalcogen element including O, S, Se, Te, and Po,
n is 1 to 5, and
R1 to R4 are each independently selected from hydrogen, an alkyl group with 1 to 8 carbon atoms, a cycloalkyl group with 3 to 6 carbon atoms, an aryl group with 6 to 12 carbon atoms, a halogen element, or an alkyl halide.

The chemical purge material may be represented by the following Chemical Formula 3:

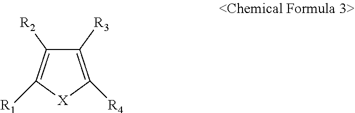

wherein X is a chalcogen element including O, S, Se, Te, and Po, and
R1 to R4 are each independently selected from hydrogen, an alkyl group with 1 to 8 carbon atoms, a cycloalkyl group with 3 to 6 carbon atoms, an aryl group with 6 to 12 carbon atoms, a halogen element, or an alkyl halide.

The chemical purge material may be represented by the following Chemical Formula 4:

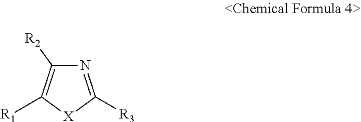

wherein X is a chalcogen element including O, S, Se, Te, and Po, and
R1 to R3 are each independently selected from hydrogen, an alkyl group with 1 to 8 carbon atoms, a cycloalkyl group with 3 to 6 carbon atoms, an aryl group with 6 to 12 carbon atoms, a halogen element, or an alkyl halide.

The method of claim 1, wherein the chemical purge material may be represented by the following Chemical Formula 5:

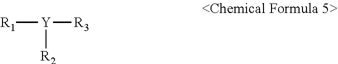

wherein Y is a pnictogen element including N, P, As, Sb, Bi, and
R1 to R3 are each independently selected from hydrogen, an alkyl group with 1 to 8 carbon atoms, a cycloalkyl group with 3 to 6 carbon atoms, an aryl group with 6 to 12 carbon atoms, a halogen element, or an alkyl halide.

The chemical purge material may be represented by the following Chemical Formula 6:

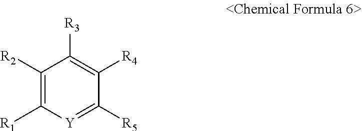

wherein Y is a pnictogen element including N, P, As, Sb, Bi, and
R1 to R5 are each independently selected from hydrogen, an alkyl group with 1 to 8 carbon atoms, a cycloalkyl group with 3 to 6 carbon atoms, an aryl group with 6 to 12 carbon atoms, a halogen element, or an alkyl halide.

The method may proceed at 50 to 700° C.

The reactant may be selected from NH₃, Hydrazine (N₂H₄), NO₂, and N₂.

The metal precursor may be a compound including at least one of a tetravalent metal including Ti, a pentavalent metal including Nb and Ta, a hexavalent metal including Mo, and a tetravalent metalloid including Si.

### BRIEF DESCRIPTION OF THE DRAWINGS

FIG. 1 is a flowchart schematically demonstrating a method of forming a thin film according to an embodiment of the present invention.

FIG. 2 is a graph schematically demonstrating a supply cycle according to the embodiment of the present invention.

FIG. 3 is a graph showing the GPC of the titanium nitride film according to TiCl₄ supply time (a)/NH₃ supply time (b)/NH₃ purge time (c).

FIG. 4 shows the step coverage by depositing a titanium nitride film on a patterned wafer (Aspect ratio 20:1).

FIG. 5 is a graph showing the GPC of the titanium nitride film according to the supply time of EMS, a chemical purge material.

FIG. 6 is a graph showing GPC and resistance of comparative example/embodiment, and comparison was made after forming thin films with the same thickness of 100 Å.

FIG. 7 shows the step coverage by depositing a titanium nitride film on a patterned wafer using EMS, a chemical purge material (Aspect ratio 20:1).

FIG. 8 is a graph of H-NMR analysis performed to confirm the interaction between EMS, a chemical purge material, and reactant.

FIG. 9 shows the results of H-NMR analysis before and after formation of an adduct.

FIG. 10 shows the results of TGA analysis.

### DETAILED DESCRIPTION

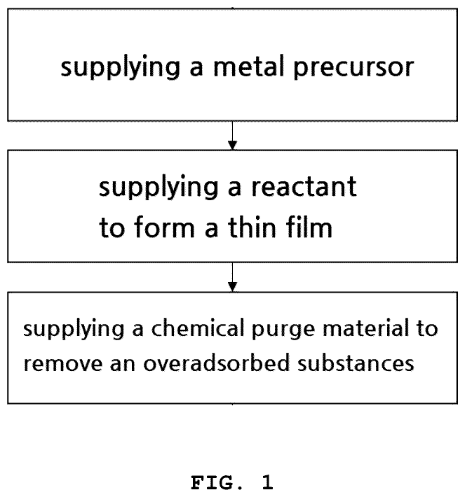

Hereinafter, embodiments of the present invention will be described using FIGS. 1 to 10. The embodiments of the present invention may include various modifications, and the scope of the present invention should not be construed to be limited to the embodiments described below.

In the conventional deposition process using a single precursor in a trench structure having a high aspect ratio (for example, 40:1 or more), a thin film deposited on an upper part (or an entrance) of the trench becomes thicker, and a thin film deposited on a lower part (or a bottom) of the trench becomes thinner. Therefore, the step coverage of the thin film is poor and not uniform.

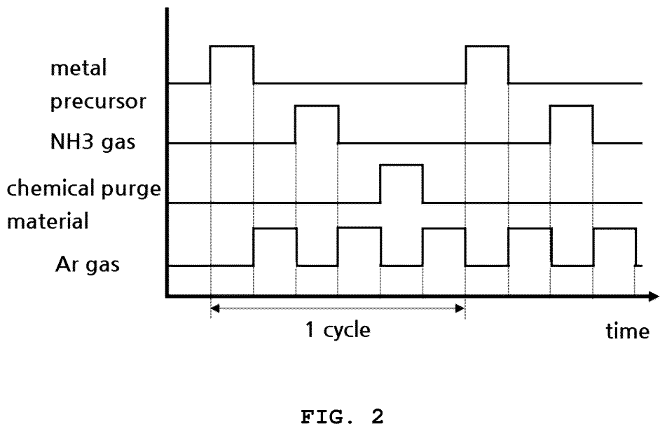

FIG. 1 is a flowchart schematically demonstrating a method of forming a thin film according to an embodiment of the present invention, FIG. 2 is a graph schematically demonstrating a supply cycle according to the embodiment of the present invention. A substrate is loaded into a process chamber, and following ALD process conditions are adjusted. ALD process conditions may include a temperature of the substrate or process chamber, a pressure in the process chamber, gas flow rate, and the temperature is 50 to 700° C.

The substrate is exposed to the metal precursor supplied to the interior of the chamber, and the metal precursor is adsorbed to the surface of the substrate. The metal precursor may be a compound including at least one of a tetravalent metal including Ti, a pentavalent metal including Nb and Ta, a hexavalent metal including Mo, and a tetravalent metalloid including Si.

Thereafter, a purge gas (for example, an inert gas such as Ar) is supplied to the interior of the chamber to discharge the unadsorbed metal precursor or by-products.

Thereafter, the substrate is exposed to a reactant supplied to the interior of the chamber, and a thin film is formed on the surface of the substrate. The reactant reacts with the metal precursor to form the thin film, and the reactant may be selected from NH₃, Hydrazine (N₂H₄), NO₂, and N₂.

Thereafter, a purge gas (for example, an inert gas such as Ar) is supplied to the interior of the chamber to discharge the unreacted material or by-products.

Thereafter, the substrate is exposed to a chemical purge material supplied to the interior of the chamber, so that the over-adsorbed NH₃ is removed. The chemical purge material may be represented by the following Chemical Formula 1:

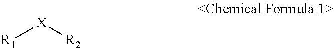

wherein X is a chalcogen element including O, S, Se, Te, and Po, and

R1 or R2 are each independently selected from hydrogen, an alkyl group with 1 to 8 carbon atoms, a cycloalkyl group with 3 to 6 carbon atoms, an aryl group with 6 to 12 carbon atoms, a halogen element, or an alkyl halide.

Also, the chemical purge material may be represented by the following Chemical Formula 2:

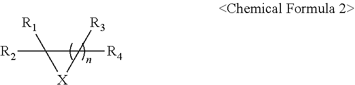

wherein X is a chalcogen element including O, S, Se, Te, and PO,
n is 1 to 5, and
R1 to R4 are each independently selected from hydrogen, an alkyl group with 1 to 8 carbon atoms, a cycloalkyl group with 3 to 6 carbon atoms, an aryl group with 6 to 12 carbon atoms, a halogen element, or an alkyl halide.

Also, the chemical purge material may be represented by the following Chemical Formula 3:

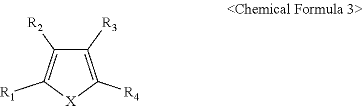

wherein X is a chalcogen element including O, S, Se, Te, and Po, and
R1 to R4 are each independently selected from hydrogen, an alkyl group with 1 to 8 carbon atoms, a cycloalkyl group with 3 to 6 carbon atoms, an aryl group with 6 to 12 carbon atoms, a halogen element, or an alkyl halide.

Also, the chemical purge material may be represented by the following Chemical Formula 4:

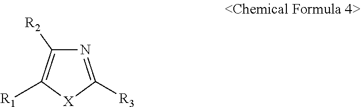

wherein X is a chalcogen element including O, S, Se, Te, and Po, and
R1 to R3 are each independently selected from hydrogen, an alkyl group with 1 to 8 carbon atoms, a cycloalkyl group with 3 to 6 carbon atoms, an aryl group with 6 to 12 carbon atoms, a halogen element, or an alkyl halide.

Also, the method of claim 1, wherein the chemical purge material may be represented by the following Chemical Formula 5:

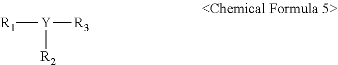

wherein Y is a pictogen element including N, P, As, Sb, Bi, and
R1 to R3 are each independently selected from hydrogen, an alkyl group with 1 to 8 carbon atoms, a cycloalkyl group with 3 to 6 carbon atoms, an aryl group with 6 to 12 carbon atoms, a halogen element, or an alkyl halide.

Also, the chemical purge material may be represented by the following Chemical Formula 6:

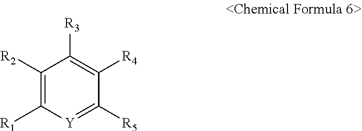

wherein Y is a pictogen element including N, P, As, Sb, Bi, and
R1 to R5 are each independently selected from hydrogen, an alkyl group with 1 to 8 carbon atoms, a cycloalkyl group with 3 to 6 carbon atoms, an aryl group with 6 to 12 carbon atoms, a halogen element, or an alkyl halide.

Thereafter, a purge gas (for example, an inert gas such as Ar) is supplied to the interior of the chamber to discharge the unreacted material or by-products.

### Comparative Example

A titanium nitride film was formed on the silicon substrate through the ALD process, the process temperature was 450° C., and the reactant was NH₃ gas.

The process of forming the titanium nitride film through the ALD process is as follows, and the following process is performed as one cycle.
1) Ar is used as a carrier gas, the titanium precursor TiCl₄ (Titanium Tetrachloride) is supplied to the reaction chamber at room temperature, and the titanium precursor is adsorbed onto the substrate.
2) Ar gas is supplied into the reaction chamber to discharge unadsorbed titanium precursors or byproducts.
3) Titanium nitride is formed by supplying NH₃ gas to the reaction chamber.
4) Ar gas is supplied into the reaction chamber to discharge unreacted substances or by-products.

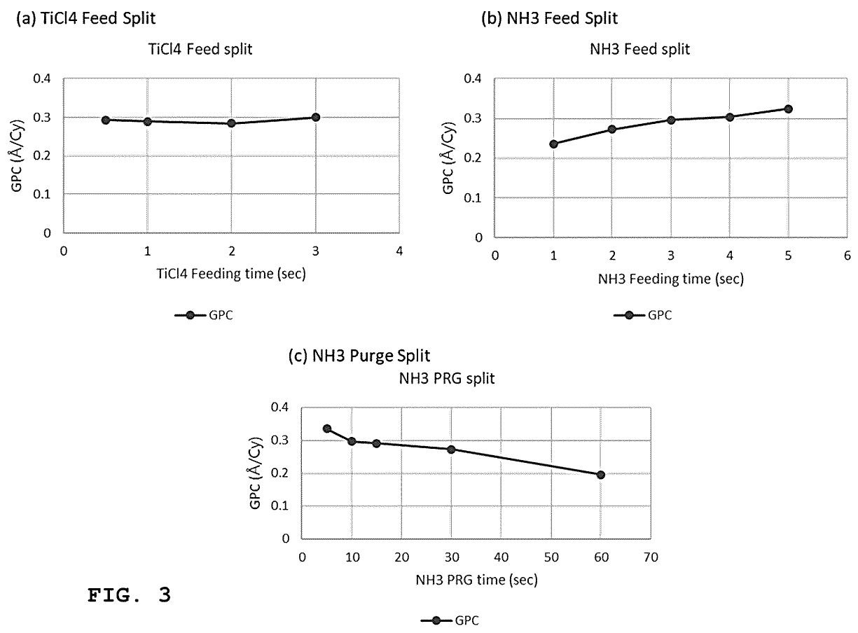

FIG. 3 is a graph showing the GPC of the titanium nitride film according to TiCl₄ supply time (a)/NH₃ supply time (b)/NH₃ purge time (c). Even if the TiCl₄ supply time is increased from 0.5 to 3, the GPC is constant at 0.3 Å, which indicates that the interaction between TiCl₄ molecules is weak and a multilayer is not formed.

When the NH₃ supply time (b) increases from 1 to 5, GPC continues to increase from 0.24 to 0.32 Å, which indicates that NH₃ over-adsorption occurs due to interactions between NH₃ molecules. In addition, the interaction between NH₃ molecules is not removed even in the subsequent Ar purge process and remains in an adsorbed state, increasing the subsequent adsorption amount of TiCl₄, indicating an increase in GPC of the titanium nitride film.

When the NH₃ purge time is increased from 5 to 60, the GPC of the titanium nitride film tends to decrease, this can be seen that by increasing Ar purge, some of the over-adsorption of NH₃ molecules is physically removed and the GPC decreases.

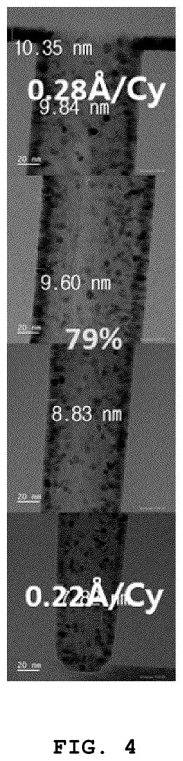

FIG. 4 shows the step coverage by depositing a titanium nitride film on a patterned wafer (Aspect ratio 20:1). The Top GPC was 0.28 A and the Bottom GPC was 0.22 A. The GPC at the Top increased by about 27% compared to the Bottom, and as a result, the step coverage was confirmed to be 79%. This is because, in the pattern structure with a high aspect ratio, a lot of NH₃ overadsorption occurs in the upper part, and in the lower part where the hole is narrow, diffusion is relatively less and NH₃ overadsorption decreases, resulting in a difference in the amount of TiCl₄ adsorption due to overadsorption on NH₃.

As a result of examining FIGS. 3 and 4, NH₃ overadsorption increases the GPC of the titanium nitride film, resulting in step coverage deterioration characteristics.

### Embodiment

A titanium nitride film was formed on the silicon substrate using EMS (ethyl methyl sulfide) as the chemical purge material described above. A titanium nitride film was formed through the ALD process, the process temperature was 450° C., and the reactant was NH₃ gas.

The process of forming the titanium nitride film through the ALD process is as follows, and the following process is performed as one cycle (see FIGS. 1 and 2).
1) Ar is used as a carrier gas, the titanium precursor TiCl₄ (Titanium Tetrachloride) is supplied to the reaction chamber at room temperature, and the titanium precursor is adsorbed onto the substrate.
2) Ar gas is supplied into the reaction chamber to discharge unadsorbed titanium precursors or byproducts.
3) Titanium nitride is formed by supplying NH₃ gas to the reaction chamber.
4) Ar gas is supplied into the reaction chamber to discharge unreacted substances or by-products.
5) chemical purge material is supplied into the reaction chamber to remove the overadsorbed NH₃.
6) Ar gas is supplied into the reaction chamber to discharge unreacted substances or by-products.

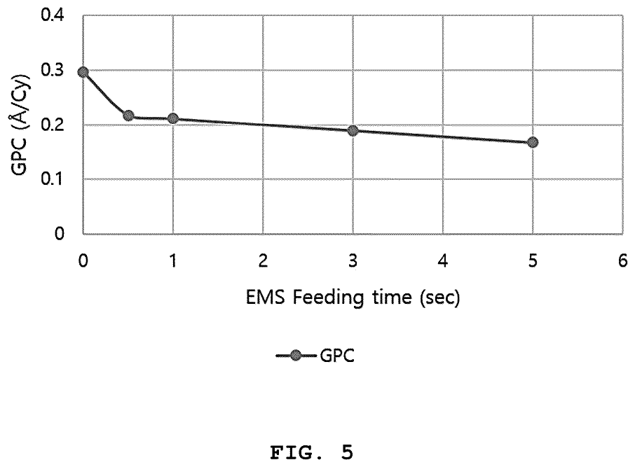

FIG. 5 is a graph showing the GPC of the titanium nitride film according to the supply time of EMS, a chemical purge material. As the EMS supply time increases, the GPC of the titanium nitride film decreases. As the supply time increases from 1 to 5, the GPC is 0.21 Å to 0.16 Å, and the GPC reduction rate is 28.6% to 43.5%, respectively.

This can be seen as having the effect of reducing the GPC of the titanium nitride film because the chemical purge material interacts with the reactant that is unevenly over-adsorbed on the surface and removes the over-adsorbed reactant in the type of a chemical purge.

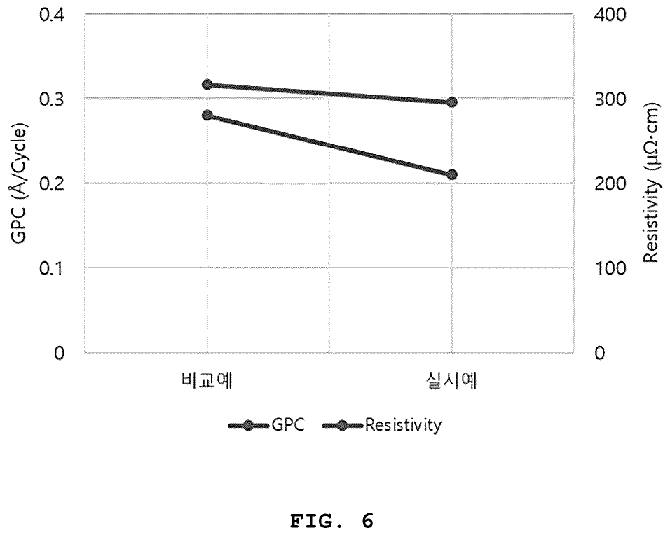

FIG. 6 is a graph showing GPC and resistance of comparative example/embodiment, and comparison was made after forming thin films with the same thickness of 100 Å. The GPC of the embodiment was 0.22 Å, showing a 21.4% GPC reduction rate compared to the GPC of the comparative example of 0.28 Å, and the resistance was confirmed to be at the same level.

This means that when a chemical purge material is used as in the embodiment, the GPC of the titanium nitride film is reduced, and the chemical purge material is removed by forming an adduct with the subsequent titanium precursor and does not remain on the surface, so the resistance appears to be equivalent.

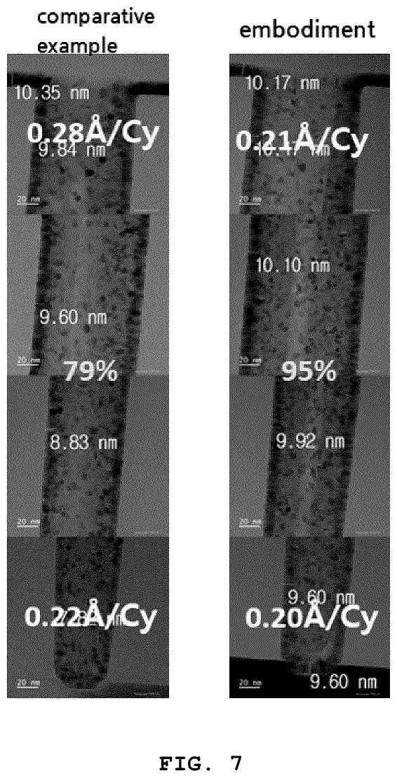

FIG. 7 shows the step coverage by depositing a titanium nitride film on a patterned wafer using EMS, a chemical purge material (Aspect ratio 20:1). Compared to the comparative example, GPC at the top of the pattern decreased by 25% from 0.28 Å to 0.21 Å, while GPC at the bottom of the pattern decreased by 9% from 0.22 Å to 0.20 Å, forming a uniform film with little significant difference in thickness between the top and bottom of the pattern.

By applying a chemical purge material, the step coverage was confirmed to have a dramatic increase of 16%p from 79% to 95%, and as a result, a titanium nitride film with excellent uniformity and step coverage was formed.

Judging from the results in FIG. 7, the titanium nitride film appears to have a GPC of about 0.2A when the overadsorption of NH₃ is removed. Table 1 below shows data comparing the process time according to physical purge and chemical purge methods as a method to remove NH3 overadsorption. When NH3 overadsorption is removed using a physical purge method (Ar purge), GPC can be lowered to 0.2 Å, but the process takes 74 s per cycle. On the other hand, when NH3 overadsorption is removed using the chemical purge method as in the Embodiment, the GPC can be lowered to 0.2 Å, similar to the physical purge method, and the process time per cycle can be shortened by more than two times from 74 s to 35 s.

In conclusion, in order to improve the step coverage of the titanium nitride film, overadsorption of NH3 must be removed, and using a chemical purge method as a NH3 removal method appears to be much more advantageous in terms of UPH than using a physical purge method.

TABLE 1

| | ALD Time (sec) | | | | | | | |
|---|---|---|---|---|---|---|---|---|
| Titanium | TiC14 | TiC14 | NH3 | NH3 | EMS | EMS | | GPC |
| Nitride | Feed | Purge | Feed | Purge | Feed | Purge | SUM | (Å/cycle) |
| Comparative | 1 | 10 | 3 | 60 | 0 | 0 | 74 | 0.2 |
| example | | | | | | | | |
| (physical | | | | | | | | |
| purge) | | | | | | | | |
| Embodiment | 1 | 10 | 3 | 10 | 1 | 10 | 35 | 0.21 |
| (chemical | | | | | | | | |
| purge) | | | | | | | | |

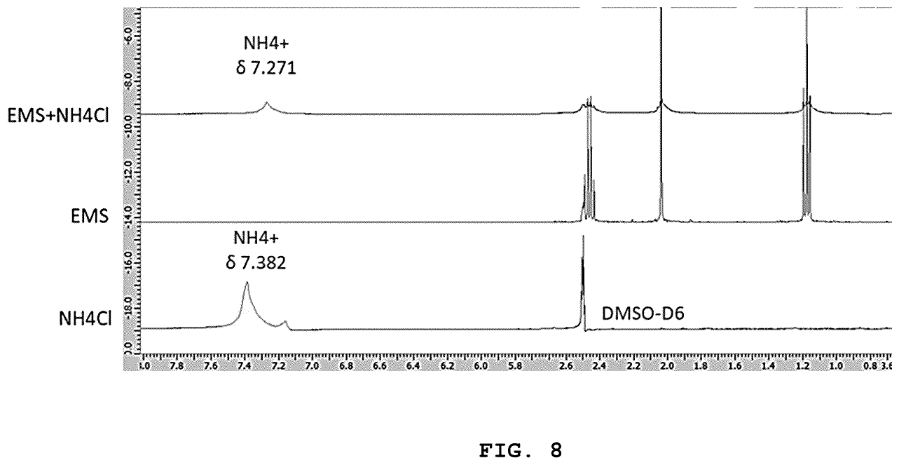

FIG. 8 is a graph of H-NMR analysis performed to confirm the interaction between EMS, a chemical purge material, and reactant. H-NMR analysis was performed after mixing the reactant, NH₄Cl, which has a similar structure to NH₃ (gas phase), and the embodiment at a 1:1 molar ratio, and Dimethyl Sulfoxide-d6 (DMSO-d6) was used as the NMR solvent.

As a result of NMR analysis of the NH₄Cl and EMS mixed solution, the NH₄+ peak has a chemical shift of 0.11 from 7.38 to 7.27 after mixing the chemical purge material, and the interaction between NH₄Cl and the chemical purge material was confirmed. Through this phenomenon, it was indirectly confirmed that there is an interaction between the chemical purge material and the reactant, NH₃. Furthermore, it appears that the chemical purge material can remove the over-adsorption of NH₃ due to the interaction.

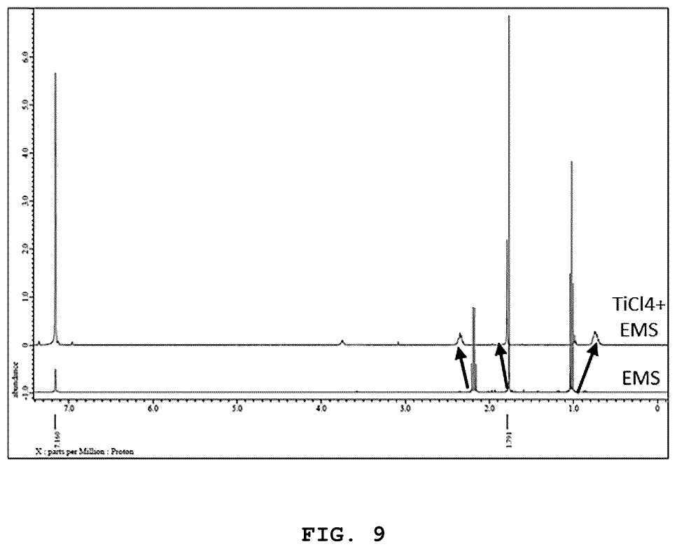

In order to confirm that the chemical purge material is removed without remaining on the surface due to the interaction between the titanium precursors after over-adsorption and removal of the reactant, the chemical purge material and titanium precursor were mixed at a 1:1 mole ratio to form an adduct, and then H-NMR and TGA analysis were performed. FIG. 9 shows the results of H-NMR analysis before and after formation of an adduct, and Benzene-d6 was used as the NMR solvent.

As a result of NMR analysis, a chemical shift of the EMS peak was confirmed after the formation of an adduct. This phenomenon means that an adduct-like interaction exists between the chemical purge material and the titanium precursor.

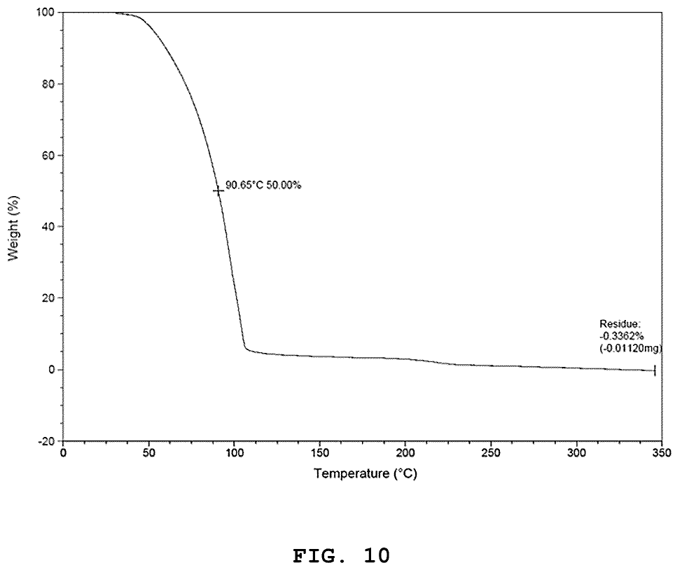

FIG. 10 shows the results of TGA analysis, the adduct formed from the chemical purge material and the titanium precursor does not have an inflection point on the graph, T ½ volatilizes well at 91° C., and it appears to exist in the form of a stable adduct as no residue remains. Furthermore, the adduct is expected to volatilize stably without remaining on the surface after forming a thin film.

In conclusion, NH₃ unevenly and excessively adsorbed on the surface is removed through NH₃-chemical purge material interaction by supplying a chemical purge material, this prevents excessive deposition of the supplied metal precursor and improves the uniformity of the nitride film.

In addition, the chemical purge material remaining on the surface is removed in the form of adduct material by the metal precursor supplied in the next step, thereby preventing the chemical purge material from being included as an impurity in the nitride film.

The chemical purge material interacts with NH₃ and forms an adduct with the metal precursor, and the adduct has the characteristic of being removed by volatilization rather than remaining on the thin film surface.

According to embodiments of the present invention, the thickness of the deposited thin film per cycle can be lowered by using a chemical purge material, and the uniformity and the step coverage of the deposited thin film can be improved.

In addition, compared to a process using a physical purge, the time required for the process can be shortened when removing over-adsorbed reactive substances using a chemical purge.

The present invention has been explained in detail with reference to embodiments, but other embodiments may be included. Accordingly, the technical idea and scope described in the claims below are not limited to the embodiments.

1. A method of forming a thin film using a chemical purge material, the method comprising:
supplying a metal precursor to the inside of a chamber oh which a substrate is placed;
purging the interior of the chamber;
supplying a reactant to the inside of the chamber so that the reactant reacts with the metal precursor to form the thin film; and
supplying a chemical purge material to the inside of the chamber so that a portion of the reactant is removed.

2. The method of claim 1, wherein the chemical purge material is represented by the following Chemical Formula 1: 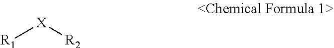
wherein X is a chalcogen element including O, S, Se, Te, and Po, and
R1 or R2 are each independently selected from hydrogen, an alkyl group with 1 to 8 carbon atoms, a cycloalkyl group with 3 to 6 carbon atoms, an aryl group with 6 to 12 carbon atoms, a halogen element, or an alkyl halide.

3. The method of claim 1, wherein the chemical purge material is represented by the following Chemical Formula 2: 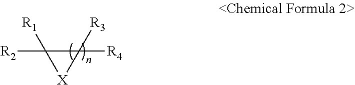
wherein X is a chalcogen element including O, S, Se, Te, and Po,
n is 1 to 5, and
R1 to R4 are each independently selected from hydrogen, an alkyl group with 1 to 8 carbon atoms, a cycloalkyl group with 3 to 6 carbon atoms, an aryl group with 6 to 12 carbon atoms, a halogen element, or an alkyl halide.

4. The method of claim 1, wherein the chemical purge material is represented by the following Chemical Formula 3: 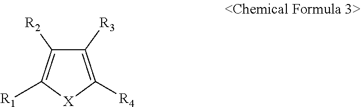
wherein X is a chalcogen element including O, S, Se, Te, and Po, and
R1 to R4 are each independently selected from hydrogen, an alkyl group with 1 to 8 carbon atoms, a cycloalkyl group with 3 to 6 carbon atoms, an aryl group with 6 to 12 carbon atoms, a halogen element, or an alkyl halide.

5. The method of claim 1, wherein the chemical purge material is represented by the following Chemical Formula 4: 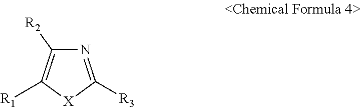
wherein X is a chalcogen element including O, S, Se, Te, and Po, and
R1 to R3 are each independently selected from hydrogen, an alkyl group with 1 to 8 carbon atoms, a cycloalkyl group with 3 to 6 carbon atoms, an aryl group with 6 to 12 carbon atoms, a halogen element, or an alkyl halide.

6. The method of claim 1, wherein the chemical purge material is represented by the following Chemical Formula 5: 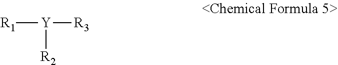
wherein Y is a pictogen element including N, P, As, Sb, Bi, and
R1 to R3 are each independently selected from hydrogen, an alkyl group with 1 to 8 carbon atoms, a cycloalkyl group with 3 to 6 carbon atoms, an aryl group with 6 to 12 carbon atoms, a halogen element, or an alkyl halide.

7. The method of claim 1, wherein the chemical purge material is represented by the following Chemical Formula 6: 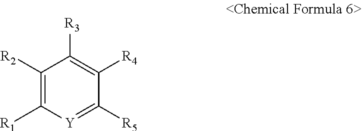
wherein Y is a pnictogen element including N, P, As, Sb, Bi, and
R1 to R5 are each independently selected from hydrogen, an alkyl group with 1 to 8 carbon atoms, a cycloalkyl group with 3 to 6 carbon atoms, an aryl group with 6 to 12 carbon atoms, a halogen element, or an alkyl halide.

8. The method of claim 1, wherein the method proceeds at 50 to 700° C.

9. The method of claim 1, wherein the reactant is selected from NH₃, Hydrazine (N₂H₄), NO₂, and N₂.

10. The method of claim 1, wherein the metal precursor is a compound including at least one of a tetravalent metal including Ti, a pentavalent metal including Nb and Ta, a hexavalent metal including Mo, and a tetravalent metalloid including Si.
